(19) United States
(12) Patent Application Publication
(10) Pub. No.: US 2006/0232938 A1
(43) Pub. Date: Oct. 19, 2006

(54) Fastening device for heat sink

(75) Inventor: Yun-Chieh Yeh, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/395,372

(22) Filed: Mar. 31, 2006

(30) Foreign Application Priority Data
Apr. 15, 2005 (TW) 094205908

(51) Int. Cl. H05K 7/20

(52) U.S. Cl. 361/704

(57) ABSTRACT

A fastening device for a heat sink, for being combined to each of two sides of a base of the heat sink for fastening the heat sink on an installing face is disclosed, wherein the two sides of the base respectively include jointing holes. The fastening device has at least a body, a positioning portion provided at the bottom of the body and a spiral fastening portion provided on the body to be combined with the base via spiral fastening components. Since the heat sink can be fastened via two of the fastening devices in conjunction with the spiral fastening components, problems in the prior art, such as complicated structure, excessive amount of components used and extra usage space required, can be solved.

### FIELD OF THE INVENTION

The present invention relates to a design of a fastening device, and more particularly, to a fastening device for fastening a heat sink to an installing face.

### BACKGROUND OF THE INVENTION

Following the revolution of integrated circuit related technologies, various kinds of power chips are developed towards the goals of miniaturization and high integration. However, this inevitably elevates the working temperature of the chips. Thus, heat dissipation is an extremely important issue in applications of the power chips.

Heat sink modules are commonly equipped in chips, such as the CPU, the south bridge chip, and the north bridge in a motherboard. These heat sink modules varies according to the working temperature of the chips to which they are applied. For example, heat sink modules applied in the south and north bridge chips usually include only one heat sink, while heat sink module applied in the CPU usually includes a heat sink and a fan. Regardless of whether the heat sink module includes a fan, the heat sink has to be adhered to the surface of heat source (e.g. CPU) and fastened to the motherboard in some ways. One way of fastening the heat sink to the motherboard is through the use of a mount and a buckling element, as disclosed in TW Utility Model Application No. 93200168 and No. 91209765.

As shown in FIG. 1, TW Utility Model Application No. 91209756 discloses a fastening module for a heat sink, including a mount 1 and two spring arms (buckling elements) 2 for fastening a heat sink 37 on a motherboard 3. A CPU socket (e.g. PGA-370) 31 is usually provided on the motherboard 3 for receiving a CPU 33 therein. A plurality of normalized positioning holes 35 are located on the motherboard 3 correspondingly around the CPU socket 31. The heat sink usually includes an outwardly expanding base 39 for providing exertion points.

The mount 1 has a framing structure for carrying and laterally securing the heat sink 37. The mount 1 also has a plurality of lockholes 11 corresponding to the positioning holes 35 to secure the mount 1 via jointing elements (e.g. screws or rivets) on the periphery of the CPU socket 31 of the motherboard 3. A plurality of buckling holes 13 are provided on the outer frame of the mount 1 for buckling of the two spring arms 2. The spring arms 2 are made of metal and used to elastically suppress the two sides of the base 39 of the heat sink 37.

This prior art uses the mount 1 and the two spring arms 2 to secure the heat sink 37. However, the structure of the mount 1 and the spring arms are complex. Moreover, the buckling strength is relatively weak. Thus, such construction is expensive and insecure. For example, the mount 1 must be framed around the periphery of the entire heat sink 37, such that the size of the mount 1 is large, resulting in material consumption. Additionally, the lockholes 11 and buckling holes 13 have to be made in different directions, so jointing mold or extra fabrication is required, resulting in high fabrication cost. Moreover, the two spring arms buckle to the corresponding holes 13 from outside of the mount 1, therefore additional operating space must be reserved on the motherboard 3 corresponding to the periphery of the mount 1. When the fastening module is applied to a motherboard with multiple CPUs, even more spaces have to be reserved for disposing the mount 1 and the spring arms 2 between each CPU, such that the design and miniaturization of the motherboard are limited. Furthermore, the spring arms 2 provides buckling strength based on the elastic deformation of the metals, such jointing status is insecure. The metals of the spring arms 2 are usually thickened to pass the dropping test after being assembled, but this makes assembly difficult since the metals are now less easy to deform.

As shown in FIG. 2, TW Utility Model Application No. 93200168 discloses another fastening device for a heat sink, including a mount 4 and a spring arm (buckling element) 5 for fastening the heat sink 37 on the motherboard 3. Since the motherboard 3 and the heat sink 37 is the same as those shown in FIG. 1, same reference numbers are used to avoid complexity. Similarly, a CPU socket 31 is provided on the motherboard 3 for receiving the CPU 33. An expanding base 39 is similarly provided to the heat sink 37.

The mount 4 has a framing structure for carrying and laterally securing the heat sink 37. The mount 4 also has a plurality of lockholes 41 to secure the mount 4 via jointing elements (e.g. screws or rivets) on the periphery of the CPU socket 31 of the motherboard 3. A positioning portion 43 is at a side of the outer frame of the mount 4 for positioning a side of the base 39 of the heat sink 37. A hook 45 is located at corner of another side of the outer frame of the mount 4, and a spring arm 5 is located at a corner opposite to the hook 45, such that the spring arm 5 can be pulled and hooked to the hook 45. The spring arms are made of metal shafts for suppressing the other side of the base 39 of the heat sink 37.

This prior art uses the mount 4 and the spring arm 5 to secure the heat sink 37. However, the structure of the mount 4 and the spring arm are nonetheless complex. Moreover, the buckling strength is relatively weak. Thus, such construction is expensive and insecure and there is an excessive amount of components used. For example, the structure of the mount 4 is even more complicated than previous mount, resulting in large amount of material consumption. In addition, a jointing mold is still needed which increases the fabrication cost. Moreover, the space needed to operate the spring arm 5 is even greater, which when applied to a motherboard with multiple CPUs, a greater amount of space must be reserved between each CPU for disposing the mount 4 and the spring arm 5 to avoid interference from each other or hindered by peripheral components. Thus, it also limits the design and miniaturization of the motherboard.

Accordingly, the two prior arts still have the problems of complicated structures, excessive amount of components used, high fabrication cost, insecure fastening, large usage space required, limitation to design and miniaturization of the motherboard that are waiting to be solved.

### SUMMARY OF THE INVENTION

In the light of forgoing drawbacks, an objective of the present invention is to provide a fastening device for heat sinks with simplified structure and less amount of components used.

Another objective of the present invention is to provide a fastening device for heat sinks to lower the fabrication cost.

Still another objective of the present invention is to provide a fastening device for heat sinks to securely fasten the heat sink.

Yet another objective of the present invention is to provide a fastening device for heat sinks with reduced usage space.

Yet another objective of the present invention is to provide a fastening device for heat sinks to eliminate limitations on designs of the motherboards.

In accordance with the above and other objectives, a fastening device for a heat sink to be combined to each of two sides of a base of the heat sink for fastening the heat sink on an installing face is provided, where the two sides of the base respectively including jointing holes. The fastening device comprises a body disposed on the installing face to be stacked by one side of the base; a positioning portion provided at the bottom of the body for fastening the body to the installing face; and a spiral fastening portion provided on the body for combining with the base via spiral fastening components.

An outer frame is vertically disposed on a top of the body for framing the periphery of the base. Preferably, the outer frame vertical extends from an outer face of the body and comprises an “n” shaped cross section. The positioning portion comprises two through holes that can correspond to normalized positioning holes on the installing face and are used in conjunction with jointing components such as screws or rivets for fastening onto a motherboard at two sides of a socket. The body can be a plastic body.

The spiral fastening portion comprises a spiral hole or a spiral shaft, and the spiral fastening components comprise corresponding screws or nuts. Preferably, the spiral fastening portion comprises two spiral holes or two spiral shafts disposed near two corners of the body, corresponding to the jointing holes on the base of the heat sink.

The heat sink can be fastened through the use of two fastening devices of the present invention in conjunction with jointing components. Not only is the size of the two fastening devices smaller than the mount of the prior art, buckling elements such as spring arms are not required. Thus simplifying the structure, greatly reducing the cost of fabrication and the number of components used. Additionally, the two fastening devices are secured to the heat sink via the jointing components, there is no need to reserve extra spaces for operating the fastening devices, thus minimizing the usage space size to almost the size of the heat sink, thus eliminating conventional limitations on design or miniaturization of the motherboard. Furthermore, a secured fastening effect can also be achieved. Thus, the fastening device for heat sinks of the present invention can solve the problems encountered in the prior art while having substantial technical improvements over the prior art.

### BRIEF DESCRIPTION OF THE DRAWINGS

The present invention can be more fully understood by reading the following detailed description of the preferred embodiments, with reference made to the accompanying drawings, wherein:

FIG. 1 shows a schematic diagram of a structure of TW Utility Model Application No. 91209756.

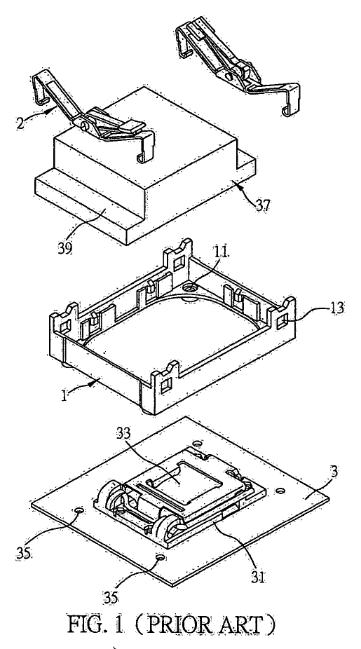

FIG. 2 shows a schematic diagram of a structure of TW Utility Model Application No. 93200168.

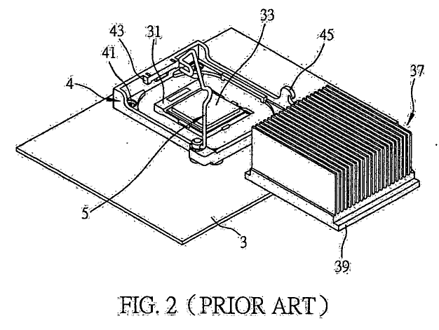

FIG. 3 shows a 3D diagram of the fastening device for heat sinks of the present invention.

FIG. 4 shows a cross-sectional diagram of the fastening device for heat sinks of the present invention.

FIG. 5 shows a status of the fastening device for heat sinks of the present invention when assembled to a motherboard.

FIG. 6 shows a fastening status of the fastening device for heat sinks of the present invention.

### DETAILED DESCRIPTION OF THE EMBODIMENTS

The following descriptions illustrate in detail the aspects of the present invention, but they should not be constructed as to limit the present invention in any way.

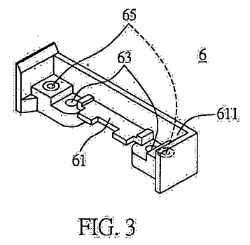

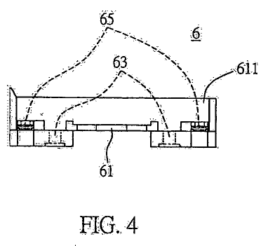

Referring to FIGS. 3 and 4, a three dimensional view and a cross-sectional view of a fastening device for heat sinks of the present invention are shown, respectively. As shown, the fastening device 6 of the present invention comprises a body 61, a positioning portion 63 disposed at the bottom of the body 61, and a spiral fastening portion 65 provided on the body 61.

In this embodiment, the body 61 is for example a plastic body and can be disposed on an installing face of a motherboard. An outer frame 611 is vertically provided on the top of the body 61. The outer frame 611 extends upwards from the outer face of the body 61 and has a “n” shaped cross section. This outer frame 611 can be used to frame a side of a base of a heat sink, so the size of the outer frame 611 is designed according to the heat sink to which it is applied.

The position portion 63 is used to secure the body 61 to the installing face. For example, in this embodiment, the positioning portion 63 can be two through holes vertically penetrating the body 61 such that they correspond to two positioning holes on the installing face in order for fastening of jointing components (e.g. screws or rivets).

The spiral fastening portion 65 provides fastening between the body 61 and the heat sink, it can for example be two spiral holes near two corners of the body 61, so as to fasten to the base of the heat sink via jointing components such as the screws. Since the body 61 can be made by plastic injecting technique, so the positioning holes 63 (e.g. two through holes) and the spiral fastening portion 65 (e.g. two spiral holes) can be made simultaneously. However, in order to ensure durability for repetitive screw operations of the spiral fastening portion 65 (e.g. spiral holes), two nuts can be pre-implanted near the two corners of the body 61 to form two spiral holes apart from inject molding or subsequent fabrication processes.

Although two spiral holes (two pre-implanted nuts) are used to illustrate the spiral fastening portion 65 in this embodiment, it should be understood that the spiral fastening portion is employed in conjunction with jointing components for fastening to the base of the heat sink, alternatively the spiral fastening portion can be designed as two bolts to be used in conjunction with jointing components such as nuts for screwing. In other words, the spiral fastening portion may be designed as two spiral shaft near the two corners of the body 61. Similarly, two inverted bolts can be pre-implanted near the two corners of the body 61 to form the two spiral shafts for ensuring the durability. These variations that employ the spiral shafts and the spiral holes are considered to be within the scope of the spiral fastening portion and will not be shown since they are well known to those skilled in the art.

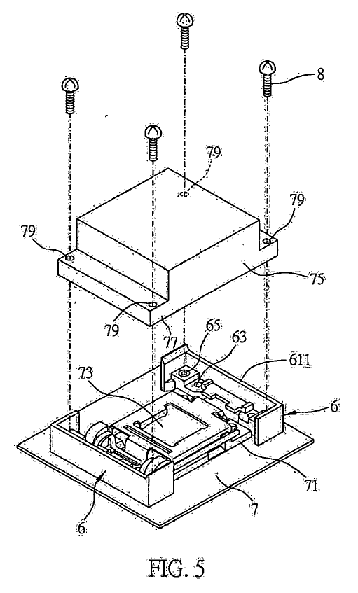

Referring now to FIG. 5, the fastening devices 6 of the present invention are combined at two sides of a base 77 of a heat sink 75 for securing the heat sink 75 on an installing face of a motherboard 7. Thus, jointing holes 79 have to be provided in the two sides of the base 77 of the heat sink 75, where the number of the jointing holes 79 corresponds to the number of the spiral fastening portion 65. In other words, two penetrating jointing holes 79 are formed at each of the two sides of the base 77 of the heat sink 75, and the spiral fastening portion 65, that is for example, two spiral holes should be located correspondingly. Those components provided on the installing face of the motherboard, for example, a CPU socket 71, a CPU 73, normalized positioning holes at periphery (not shown), the heat sink 75 and the base 77 are not the main features of the present invention, thus will not be discussed further.

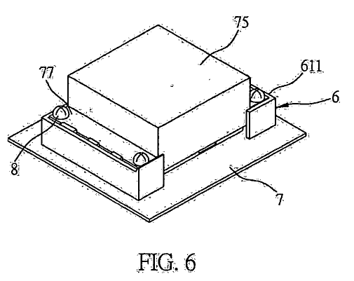

Referring again to FIG. 5 and to FIG. 6, the two fastening devices 6 are provided on areas of the motherboard 7 that correspond to two sides of the periphery of the CPU socket 71, and can be fastened via jointing components, such as screws or rivets, penetrating the positioning portion 63 and positioning holes (not shown) thereof. The area between the two outer frame 611 of the two fastening device 6 corresponds exactly to the size of the base 77 of the heat sink 75 for receiving the heat sink 75 therein, i.e. two sides of the base 77 of the heat sink 75 are framed by the two fastening devices 6. The jointing holes 79 in two sides of the base 77 of the heat sink 75 correspond to the spiral fastening portion 65 of the two fastening device 6. Jointing components, such as screws or spiral shafts, penetrate the jointing holes 79 and screw into the spiral fastening portion 65, thereby securing the heat sink 75.

It should be noted that the above descriptions are for illustrative purposes only; the fastening device 6 for heat sinks of the present invention can be employed to fasten the heat sinks onto any installing face of, for example, a circuit board with a plurality of positioning holes, apart from the motherboard. Moreover, the heat sink described is not limited to the aspects shown in the figures, but any heat sinks with several or two jointing holes on the base thereof can be utilized. In addition, in the structure design of the fastening device 6 of the present invention, the relative positions of the positioning portion 63 and the spiral fastening portion 65 on the body 61 may not depend on the numbers and relative positions shown in the figures or the embodiments, but rather on the heat sink and the installing face. For example, the positioning portion 63 (shown as two penetrating holes in the figures) may be at an outer side of the spiral fastening portion 65 (shown as two spiral holes in the figures).

In summary, a heat sink can be fastened through the use of two fastening devices of the present invention in conjunction with jointing components. Not only is the size of the two fastening devices smaller than the mount of the prior art, buckling elements such as spring arms are not required. Thus simplifying the structure, greatly reducing the cost of fabrication and the number of components used. Additionally, the two fastening devices are secured to the heat sink via the jointing components, there is no need to reserve extra spaces for operating the fastening devices, thus minimizing the usage space size to almost the size of the heat sink, thus eliminating conventional limitations on design or miniaturization of the motherboard. Furthermore, a secured fastening effect can also be achieved.

Thus, the fastening device for heat sinks of the present invention can solve the problems encountered in the prior art. It also have industrial applicability and substantial technical improvements over the prior art as described above, including simplified structure, reduced number of components used, lowered fabrication costs, secured fastening effect, reduced usage space, elimination of limitations on design and miniaturization of the motherboard etc.

The above specific embodiments are for illustrating the features of the present invention, and should not be construed as to limit the implementations of the present invention. The present invention can be practiced by other embodiments, and should therefore cover various modifications and variations made to the herein-described details of the present invention, provided they fall within the scope of the present invention as defined in the following appended claims.

What is claimed is:

1. A fastening device for a heat sink, for being combined to each of two sides of a base of the heat sink to fasten the heat sink on an installing face, wherein the two sides of the base respectively include jointing holes, the fastening device comprising:
a body disposed on the installing face, allowing one of the two sides of the base to be stacked on the body;
a positioning portion provided at bottom of the body, for fastening the body to the installing face; and
a spiral fastening portion provided on the body, for being combined with the base via spiral fastening components.

2. The fastening device as claimed in claim 1, wherein an outer frame is vertically disposed on top of the body, for framing periphery of the base.

3. The fastening device as claimed in claim 2, wherein the outer frame is vertically extended from an outer face of the body and comprises an “n” shaped cross section.

4. The fastening device as claimed in claim 1, wherein the positioning portion comprises two through holes.

5. The fastening device as claimed in claim 1, wherein the spiral fastening portion comprises at least one spiral hole and the spiral fastening components comprise screws.

6. The fastening device as claimed in claim 5, wherein the spiral fastening portion comprises two spiral holes.

7. The fastening device as claimed in claim 6, wherein the two spiral holes are near two corners of the body.

8. The fastening device as claimed in claim 6, wherein nuts are pre-implanted in the body to form the spiral holes.

9. The fastening device as claimed in claim 1, wherein the spiral fastening portion comprises at least one spiral shaft and the spiral fastening components comprise screws.

10. The fastening device as claimed in claim 9, wherein the spiral fastening portion comprises two spiral shafts.

11. The fastening device as claimed in claim 10, wherein the two spiral shafts are near two corners of the body.

12. The fastening device as claimed in claim 1, wherein the installing face is a circuit board with a plurality of positioning holes.

13. The fastening device as claimed in claim 12, wherein the circuit board is a motherboard.

14. The fastening device as claimed in claim 1, wherein the body is a plastic body.
